(19) United States
(12) Patent Application Publication
(10) Pub. No.: US 2025/0181247 A1
(43) Pub. Date: Jun. 5, 2025

(54) EFFICIENCY-IMPROVED BACKGROUND MEDIA SCAN MANAGEMENT OF NON-VOLATILE MEMORY DEVICES

(71) Applicant: Micron Technology, Inc., Boise, ID (US)

(72) Inventor: Marco Redaelli, Munich (DE)

(21) Appl. No.: 18/935,914

(22) Filed: Nov. 4, 2024

Related U.S. Application Data
(60) Provisional application No. 63/605,711, filed on Dec. 4, 2023.

(51) Int. Cl. G06F 3/06; G11C 16/04

(52) U.S. Cl. CPC G06F 3/0613; G06F 3/0653; G06F 3/0659; G06F 3/0679; G11C 16/0483

(57) ABSTRACT

A system includes an integrated circuit (IC) memory device with memory cells. A volatile memory device includes a queue to store indicators for one or more blocks of the memory cells that are to be refreshed. A processing device is operatively coupled to the IC memory device and the volatile memory device. The processing device detects initiation of a power-down operation of the system. In response to detecting the initiation of the power-down operation, the processing devices detects one or more indicators remain in the queue corresponding to the one or more blocks and sends a signal to a host system coupled to the processing device. The signal indicates to the host system to wait to complete the power-down operation until writing refresh data, from the one or more blocks, to one or more erased blocks of the IC memory device is complete.

### CLAIM OF PRIORITY

The present application claims the benefit under 35 U.S.C. § 119(e) of U.S. Provisional Patent Application No. 63/605,711, filed Dec. 4, 2023, which is incorporated herein by this reference.

### TECHNICAL FIELD

Embodiments of the disclosure generally relate to memory sub-systems, and more specifically, relate to efficiency-improved background media scan management of non-volatile memory devices.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The present disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system in accordance with some embodiments of the present disclosure.

FIG. 2A illustrates schematically a distribution of threshold control gate voltages for a flash memory cell capable of storing three bits of data by programming the memory cell into at least eight charge states that differ by the amount of charge on the cell's floating gate, in accordance with some embodiments.

FIG. 2B is a graph of an example set of threshold voltage distributions of multiple memory cells of a memory array in a memory device in accordance with some embodiments.

FIG. 2C is a graph of two example threshold voltage distributions of multiple memory cells of a memory array in a memory device in accordance with some embodiments.

FIG. 3 is a flow diagram of an example method for executing data refresh in particular memory blocks based on results of background media scans of those memory blocks in accordance with some embodiments.

FIG. 4 is a flow diagram of an example method for efficiently managing background media scans in non-volatile memory devices in accordance with some embodiments.

FIG. 5 is a block diagram of an example computer system in which embodiments of the present disclosure can operate.

### DETAILED DESCRIPTION

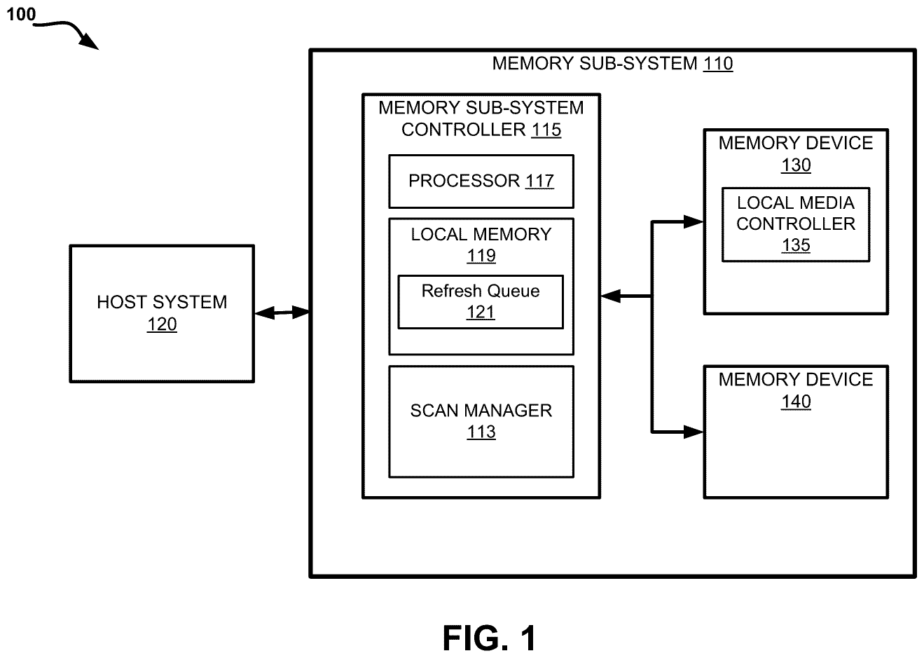

Aspects of the present disclosure are directed to efficiency-improved background media scan management of non-volatile memory devices. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high-density non-volatile memory devices where retention of data is desired when no power is supplied to the memory device. One example of non-volatile memory devices is a negative-and (NAND) memory device. Other examples of non-volatile memory devices (to include, integrated circuit (IC) memory devices) are described below in conjunction with FIG. 1. Ann IC non-volatile memory device is a package of one or more dies. Each die can include one or more planes. For some types of non-volatile memory devices (e.g., NAND devices), each plane can include a set of physical blocks. In some embodiments, each block can include multiple sub-blocks. Each block can include a set of pages. Each page can include a set of memory cells (“cells”). A cell is an electronic circuit that stores information. Depending on the cell type, a cell can store one or more bits of binary information, and has various logic states that correlate to the number of bits being stored. The logic states can be represented by binary values, such as “0” and “1”, or combinations of such values.

A memory device can include cells arranged in a two-dimensional or three-dimensional grid. Memory cells can be etched onto a silicon wafer in an array of columns connected by conductive lines (also hereinafter referred to as bitlines or BLs) and rows connected by conductive lines (also hereinafter referred to as wordlines or WLs). A wordline can refer to a conductive line that connects control gates of a set (e.g., one or more rows) of memory cells of a memory device that are used with one or more bitlines to generate the address of each of the memory cells. In some embodiments, each plane can carry an array of memory cells formed onto a silicon wafer and joined by conductive BLs and WLs, such that a wordline joins multiple memory cells forming a row of the array of memory cells, while a bitline joins multiple memory cells forming a column of the array of memory cells. The intersection of a bitline and wordline constitutes the address of the memory cell. A block hereinafter refers to a unit of the memory device used to store data and can include a group of memory cells, a wordline group, a wordline, or individual memory cells addressable by one or more wordlines. One or more blocks can be grouped together to form separate partitions (e.g., planes) of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types.

A cell can be programmed (written to) by applying a certain voltage to the cell, which results in an electric charge being held by the cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage Vₜ (also referred to as the “threshold voltage”) such that the source-drain electric current is low for the control gate voltage (V_{CG}) being below the threshold voltage, V_{CG}<Vₜ. The current increases substantially once the control gate voltage has exceeded the threshold voltage, V_{CG}>Vₜ. Because the actual geometry of the electrodes and gates varies from cell to cell, the threshold voltages can be different even for cells implemented on the same die. The cells can, therefore, be characterized by a distribution P of the threshold voltages, P(Q,Vₜ)=dW/dVₜ, where dW represents the probability that any given cell has its threshold voltage within the interval [Vₜ, Vₜ+dVₜ] when charge Q is placed on the cell.

A programming operation can be performed by applying a series of incrementally increasing programming pulses to the control gate of a memory cell being programmed. A program verify operation after each programming pulse can determine the threshold voltage of the memory cell resulting from the preceding programming pulse. When memory cells are programmed, the level of the programming achieved in a cell (e.g., the Vₜ of the cell) is verified, in effect, by comparing the cell Vₜ to a target (i.e., desired) program verify (PV) voltage level. The PV voltage level can be provided by an external reference.

A program verify operation can include applying a ramped voltage to the control gate of the memory cell being verified. When the applied voltage reaches the threshold voltage of the memory cell, the memory cell turns on and sense circuitry detects a current on a bit line coupled to the memory cell. The detected current activates the sense circuitry and determines the present threshold voltage of the cell. The sense circuitry can determine whether the present threshold voltage is greater than or equal to the target threshold voltage. If the present threshold voltage is greater than or equal to the target threshold voltage, further programming is not needed. Otherwise, programming continues in this manner with the application of additional program pulses to the memory cell until the target Vₜ and data state is achieved.

Accordingly, certain non-volatile memory devices can use a demarcation voltage (i.e., a read reference voltage) to read data stored at memory cells. For example, a read reference voltage (also referred to herein as a “read voltage”) can be applied to the memory cells, and if a threshold voltage of a specified memory cell is identified as being below the read reference voltage that is applied to the specified memory cell, then the data stored at the specified memory cell can be read as a particular value (e.g., a logical ‘1’) or determined to be in a particular state (e.g., a set state). If the threshold voltage of the specified memory cell is identified as being above the read reference voltage, then the data stored at the specified memory cell can be read as another value (e.g., a logical ‘0’) or determined to be in another state (e.g., a reset state). Thus, the read reference voltage can be applied to memory cells to determine values stored at the memory cells. Such threshold voltages can be within a range of threshold voltages or reflect a normal distribution of threshold voltages.

A memory device can exhibit threshold voltage distributions P(Q, Vₜ) that are narrow compared with the working range of control voltages tolerated by the cells of the device. Accordingly, multiple non-overlapping distributions P(Qₖ, Vₜ) can be fit into the working range allowing for storage and reliable detection of multiple values of the charge Qₖ, k=1, 2, 3 . . . . The distributions are interspersed with voltage intervals (“valleys”) where none (or very few) of the cells of the device have their threshold voltages. Such valley margins (also known as read window budget (RWB) can, therefore, be used to separate various charge states Qₖ. The logical state of the cell can be determined by detecting, during a read operation, between which two valleys the respective threshold voltage Vₜ of the cell resides. This effectively allows a single memory cell to store multiple bits of information: a memory cell operated with 2N−1 well-defined valleys and 2N distributions is capable of reliably storing N bits of information. Specifically, the read operation can be performed by comparing the measured threshold voltage Vₜ exhibited by the memory cell to one or more reference voltage levels corresponding to known valley voltage levels (e.g., centers of the valleys) of the memory device in order to distinguish between the multiple logical programming levels and determine the programming state of the cell.

Precisely controlling the amount of the electric charge stored by the cell allows multiple logical states to be distinguished, thus effectively allowing a single memory cell to store multiple bits of information. One type of cell is a single level cell (SLC), which stores 1 bit per cell and defines 2 logical states (“states”) (“1” or “L0” and “0” or “L1”) each corresponding to a respective Vₜ level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective Vₜ level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective Vₜ level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

In some memory sub-systems, a read operation can be performed by comparing the measured threshold voltages (Vₜ) exhibited by the memory cell to one or more reference voltage levels in order to distinguish between two logical states for single-level cell (SLCs) and between multiple logical states for multi-level cells. In various embodiments, a memory device can include multiple portions, including, e.g., one or more portions where the sub-blocks are configured as SLC memory, one or more portions where the sub-blocks are configured as multi-level cell memory. In these embodiments, the multi-level cell memory can include multi-level cell (MLC) memory that can store two bits of information per cell, tri(ple)-level cell (TLC) memory that can store three bits of information per cell, and/or one or more portions where the sub-blocks are configured as quad-level cell (QLC) memory that can store four bits per cell. The voltage levels of the memory cells in TLC memory form a set of 8 programming distributions representing the 8 different combinations of the three bits stored in each memory cell. Depending on how the memory cells are configured, each physical memory page in one of the sub-blocks can include multiple page types. For example, a physical memory page formed from single level cells (SLCs) has a single page type at a single page level referred to as a lower logical page (LP). Multi-level cell (MLC) physical page types can include pages at multiple page levels such as LPs and upper logical pages (UPs). TLC physical page types include LPs, UPs, and pages at an additional page level referred to as extra logical pages (XPs), and QLC physical page types include LPs, UPs, XPs and pages at a further page level referred to as top logical pages (TPs). The different page types (LP, UP, XP, TP, etc.) can be referred to as levels within a page level hierarchy that can exist within the same physical memory page. For example, a physical memory page formed from memory cells of the QLC memory type can have a total of four logical pages, where each logical page can store data distinct from the data stored in the other logical pages associated with that physical memory page, which is herein referred to as a “page.”

In various embodiments, to improve data retention on minimally-accessed logical block addresses (LBAs), a memory sub-system controller (e.g., processing device) performs a background media scan to read data periodically from the memory blocks. As such, the host system can either relocate data stored in a block to another block to refresh the data, or the controller can monitor a bit error rate (BER) of a page or block to determine whether the page or block is decaying. Data retention is the length of time the storage media (e.g., NAND or other non-volatile memory (NVM) storage media) in a memory device retains data with biased or unbiased conditions. Because data retention is limited, memory device scanning and refresh may be performed and may be managed by the memory sub-system controller through a background media scan (BGMS) process.

In some embodiments, an inverse relationship exists between data retention and either the Total Byte Written (TBW) or the temperature that affects a device over time. For example, when either or both TBW and temperature increase, data retention decreases, making a refresh operation necessary. From the perspective of data retention, some memory devices comply with JESD47 that, in case of an unbiased device, can be summarized as follows: 5 years at 55° C. at 10% of TBW or 1 year at 55° C. at maximum TBW. This data retention versus TBW may apply to both multi-level cells and single-level cell namespaces. These values of years, temperature, and TBW are illustrated only by way of example, and are not intended to be limiting.

More specifically, memory devices can experience random workloads over the course of their operation that impact the Vₜ distributions of their memory cells. For example, the Vₜ distributions can be shifted to higher or lower values. A temporal shift of Vₜ (i.e., a shift of the Vₜ distributions over a period of time), for example, can be caused by a quick charge loss (QCL) that occurs soon after programming and by a slow charge loss (SCL) that occurs as time passes during data retention. To compensate for various Vₜ distribution shifts, calibration operations can be performed (to include a refresh operation) in order to adjust the read level voltages, which can be done on a distribution-by-distribution basis, as higher Vₜ levels tend to incur more temporal shifting than do lower Vₜ levels. In certain memory devices, read voltage level adjustments can be performed based on values of one or more data state metrics obtained from a sequence of read and/or write operations. In an illustrative example, the data state metric can be represented by a raw bit error rate (RBER), which refers to the error rate in terms of a measure of bits that contain incorrect data (i.e., bits that were sensed erroneously) when a data access operation is performed on a memory device (e.g., a ratio of the number of erroneous bits to the number of all data bits stored in a certain portion, such as a specified block, of the memory device). In these memory devices, sweep reads (or scans) can be performed to create RBER/log likelihood ratio (LLR) profiles for error correction code (ECC) and select the most efficient profile. Such calibrations can be performed to accurately predict where valleys are located between Vₜ distributions for purposes of accurately reading data from the memory cells.

Because of the incorrect Vₜ sensed for some cells when performing read operations, the rate at which error handling operations (e.g., remedial ECC operations) are triggered (referred to herein as a “trigger rate”) by the memory device during the read operations can be high, even for memory devices in which calibration techniques are employed to address the temporal Vₜ shifts. As used herein, read trigger rate refers to a measure (e.g., a count, or frequency) of read operations that trigger additional read error handling operations (e.g., remedial ECC operations), caused by a high raw bit error rate (RBER) encountered during the read operation. A high read trigger rate can be observed in QLC NAND devices despite the implementation of static calibration. Thus, the read trigger rate can correspond to the probability that an initial attempt to retrieve data fails (e.g., when a code word fails hard decode) and therefore directly correlates with system performance and quality of service (QoS). For example, if a set of data (e.g., codeword) fails a hard bit read operation, an error recovery flow will be triggered and increase the latency of the data being retrieved. This delay negatively impacts QoS and uses additional computing resources. This effect and its negative impacts on memory devices are evident in storage applications for mobile, embedded storage, storage (consumer, client, datacenter devices) or external customers.

Furthermore, memory cells in a memory device can wear out over time or with increased temperature as their ability to retain a charge (i.e., data) and, consequently, to remain at a particular programming level deteriorates with the passage of time as well as with increased use and/or exposure to higher temperatures. Thus, in some cases, the quality of data retention can be reflected by a measurable degree of data degradation indicated by an error rate experienced during a read operation performed on the data. This degree of degradation can be reflected by and can correspond to various respective values of data state metrics (e.g., valley shift values, read counts, valley width values, error counts, RBER, RWB, etc.). These values (e.g., of valley shift or read count) and their corresponding indication of data retention quality or capability on a memory device, can be known from statistics and historical data obtained from scans (such as BGMS) and testing of various memory devices. Furthermore, the effect of these temporal shifts on the trigger rate can be expected to worsen with the additional passage of time and increased use of the device.

While different calibrations may be performed to track changing the read voltage reference (or demarcation voltage) due to temporal shifting of various Vₜ distributions of memory cells, the present disclosure is focused on performing refresh of the data in the memory cells. For example, when a block of memory is sampled by a read-based health scan, particular Vₜ levels or particular threshold levels of other tracked attributes may trigger the qualification of that memory block for a background refresh, which will be discussed in more detail. In some embodiments, the background health scans are performed to avoid extensive ECC events, and certainly to avoid uncorrectable errors (e.g., UECC events). Thus, in some embodiments, the memory sub-system controller performs one or more sampling background scans of the one or more blocks and determines that the one or more blocks qualify for refresh based on an attribute of self-monitoring analysis and reporting technology (S.M.A.R.T.) data obtained from the one or more sampling background scans. In different embodiments, the attribute includes total bytes written (TBW), temperature change over time, or a data state metric such as those just discussed.

In response to qualifying for a refresh, the data in that block may be stored in a refresh queue in volatile memory of the memory sub-system, which can be local memory of the memory sub-system controller, for example. This refresh data is then programmed into a new block (e.g., an erased block) of memory in the memory device, thus updating the Vₜ levels of the memory cells for this data, and commensurately more healthy read voltage reference levels. Where the data is programmed into multi-level cells (e.g., MLC, TLC, QLC, PLC data), the programming of the data to the new blocks is referred to as folding because of the dimensionality of that data, which typically takes longer to program than to SLC memory. Because of the time required to fold this data into new memory blocks, a power-down operation of the memory sub-system (and thus of the memory device) may interrupt the memory refresh operation for one or more blocks of memory. In various embodiments, the power-down operation may be either a power-off (e.g., shutdown) or a move to a low-power state such as a sleep state. When this happens, the refresh data, which have been folded already and stored in volatile memory, may be lost or increased wear on the memory device may be incurred in recovering the refresh data. If the data is able to be recovered, the recovery process also causes delay in the power-up operation, which negatively impacts QoS.

In various embodiments, to avoid the possibility of losing refresh data or other negative impacts from the recovery of the refresh data, the disclosed system, device, and methods provide a way to complete the refresh operations of those memory blocks for which indicators of blocks being refresh are enqueued in the volatile memory. In some embodiments, for example, the controller, in response to detecting initiation of a power-down operation of the memory sub-system and detecting that indicator(s) remain in the queue, signals the host system to delay completion of the power-down operation until refresh data, from blocks associated with the indicator(s), are completely written back to new memory blocks.

In at least some embodiments, the controller sends a signal to the host system to indicate to the host system to wait to complete the power-down operation until writing the refresh data, from one or more blocks, to one or more erased blocks of the IC memory device is complete. In some embodiments, the controller determines an amount of time to delay the power-down operation based on how long it would take to refresh the data from a number and data type of the one or more blocks. In these embodiments, the amount of time to delay the power-down operation is included in the signal, thus informing the host system how long to wait until completing powering off the memory sub-system. In other embodiments, additional information may be included in the signal to the host to enable the host to make an informed decision whether or not delay until the data refresh is completed for blocks associated with indicators stored in the refresh queue. In this way, the refresh data is protected and safely programmed to the memory device before complete power off of the memory sub-system, or these refreshes of some blocks are delayed until the memory device (or sub-system) powers back on.

In various embodiments, the host system polls the controller (e.g., a register of the controller) that indicates whether the volatile memory still contains indicators associated with refresh data that needs to be programmed to the IC memory device. Thus, a response to that polling inquiry may be considered the signal from the memory sub-system. In this way, the host system may also be configured to be aware of or waiting for such a signal to know when it is safe to completely power off the memory sub-system and thus also the memory device.

Advantages of the present disclosure include avoiding the loss of refresh data due to powering off the memory sub-system, thus enhanced data retention and enhanced coordination between the host system and the non-volatile memory devices in terms of the safe timing of completing a power-down operation. This enhanced coordination may be especially beneficial to increasing the reliability and robustness of non-volatile memory devices in automotive environments where powering up and down is performed more frequently and lower error rates or data loss rates are required in design specifications. For example, the enhanced coordination between the host system and the non-volatile memory devices enables better communication and synchronization in relation to refresh and power-down operations, ensuring optimal utilization of BGMS resources and minimization of performance degradation. Advantages also include reducing the read trigger rates associated with SCL and static read voltage level calibration on memory devices, thus reducing the latency of memory access operations performed by the memory device. This enhanced coordination between host system and the memory sub-system and the reduction in read trigger rates improves the quality of service (QoS) that users will experience in accessing data during read operations and without the risk of losing refresh data. Other advantages will be apparent based on the additional details provided herein.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such media or memory devices.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. The host system 120 can provide data to be stored at the memory sub-system 110 and can request data to be retrieved from the memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Channel, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level cells (SLC) can store one bit per cell. Other types of memory cells, such as multi-level cells (MLCs), triple level cells (TLCs), quad-level cells (QLCs), and penta-level cells (PLCs) can store multiple bits per cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local media controller 135) on the die and a controller (e.g., memory sub-system controller 115) for media management within the same memory device package. An example of a managed memory device is a managed NAND (MNAND) device.

In some embodiments, the memory sub-system 110 includes a scan manager 113 that can perform scans on memory device 130 to obtain values of data state metrics on the memory device 130. In several embodiments, the scan manager 113 can receive and respond to data access requests from host system 120 and manage calibration of applied voltages (i.e., manage compensation for Vₜ shifts) by controlling the voltages that are applied during read operations on memory device 130. In some embodiments, the memory sub-system controller 115 includes at least a portion of the scan manager 113. In some embodiments, the scan manager 113 is part of the host system 120, an application, or an operating system. In other embodiments, local media controller 135 includes at least a portion of scan manager 113 and is configured to perform the functionality described herein.

Memory scan manager 113 can perform various actions such as handling the interactions of memory sub-system controller 115 with the memory device 130 of memory sub-system 110. For example, in some embodiments, the scan manager 113 can transmit, to memory device 130 memory access commands that correspond to requests received by memory sub-system 110 from host system 120, such as program commands, read commands, and/or other commands, to include protocol-based commands associated with health-based scans. Besides, the scan manager 113 can receive data from memory device 130 such as data retrieved in response to a read command or a confirmation that a write/program command was completed successfully.

In some embodiments, the memory sub-system controller 115 can include a processor 117 (e.g., processing device) configured to execute instructions stored in local memory 119 for performing the operations described herein. In other embodiments, the operations described herein are performed by the scan manager 113. In yet other embodiments, local media controller 135 can perform the operations described herein. In at least one embodiment, memory device 130 can include a memory access manager configured to carry out memory access operations (e.g., operations performed in response to memory access commands received from processor 117 or from the scan manager 113). In some embodiments, local media controller 135 can include at least a portion of scan manager 113 and can be configured to perform the functionality described herein. In some of these embodiments, the scan manager 113 can be implemented on memory device 130 using firmware, hardware components, or a combination of firmware and hardware components. In an illustrative example, the scan manager 113 can receive, from a requesting component, such as processor 117, a request to read a data page of the memory device 130, and respond to it by performing the requested read operation. For the purposes of this disclosure, a read operation can include a series of read strobes (also referred to as pulses), such that each strobe applies a specific read voltage level to a particular wordline of a memory device 130. In the read operation, each strobe can be used to compare the estimated threshold voltages Vₜ of a set of memory cells to one or more read voltage levels corresponding to the expected positions of the voltage distributions of the memory cells.

The scan manager 113 can, in some embodiments, perform various scans on data storage elements (e.g., pages) of the memory device 130. For the purposes of this disclosure, data storage elements, such as cells (e.g., connected within an array of WLs and BLs), pages, blocks, planes, dies, as well as groups and combinations of one or more of the foregoing elements, can be referred to as “data storage units.” As noted, these scans can produce measurements of a variety of different data state metrics including error count, RBER, valley shift, valley width, read count, etc. For the purposes of the present disclosure, a read count can refer to the number of times the data stored in a particular location of the memory device 130 has been accessed (i.e., read). The scan manager 113 can also track total bytes written (TBW) and temperature change of various blocks of memory or block families where the blocks are grouped based on being programmed around the same time and at the same temperature.

In some embodiments, the term Background Media Scan (BGMS) refers to a low-priority firmware process performed by the scan manager 113. The BGMS process can resume with regular cadence to progressively read through a select number of pages (e.g., a sampling of pages) in each fully written memory block (multi-level cell or SLC) over a relatively long-time interval. This process can mitigate outlier BER tail surprises which can be exacerbated by memory retention, read disturb, cross-temperature effects, and defectivity of different portions of memory. Thus, BGMS may proactively skim the least capable blocks (“weak blocks”), preventing these blocks from entering into a condition requiring extensive ECC, or worse yet, a UECC event.

The purpose of BGMS can be to eventually sample every block in the memory device 130, but not every page. Data within a block should be of a similar nature. For example, all data within a block—the data's age, the temperature at which the data was programmed, and the temperature at which the data is read—should all be similar so that a given page is representative of all data in the block. Furthermore, the BGMS sample rate and sampling method may be designed to ensure multiple samples are taken from every block in a way that covers all expected use cases and the majority of memory disturb mechanisms. From power on, BGMS read events should begin at the oldest fully programmed memory block and step towards the newest programmed memory block. Considering the BGMS re-trigger cadence, the oldest memory blocks matter the most. This procedure may continue indefinitely on a fixed sampling cadence. It can be expected that all fully written memory blocks will be scanned on the cycle of a fixed cadence. BGMS thus acts on all user data blocks and FW blocks (contains FTL meta-data).

In various embodiments, the following non-exhaustive list of conditions trigger BGMS scanning, including 1) when the last page of a block is written, one super-page may be checked next into the scan list; 2) after the host system 120 reads 1 (“one”) gigabyte (GB) of cumulative data in any order, one super-page may be scanned; and 3) after waking up from idle (active-idle/PS3/PS4), N/30 super-pages may be scanned, where N is the idle time in seconds. For example, at the exit of a 63-second-long idle period, two super-pages may be scanned. A super-page is a page worth of data stored across multiple dies that the controller 115 can read from or write to in parallel. The effect of BGMS is to enqueue indicators of the “weak blocks” (for imminent refresh/folding) in a refresh queue 121 of the local memory 119, e.g., in volatile memory of the memory sub-system 110. Even a regular host read may cause “weak blocks” to be scheduled for refresh, which will be discussed in more detail. Thus, queuing indicators (such as block identifiers or numbers that are associated with respective memory blocks) may be a way of scheduling corresponding memory blocks for refresh. In some embodiments, the scan manager 113 triggers refresh to happen during a host write. In some embodiments, the BGMS scanning is performed during idle time of the memory device 130 so as not to overly impact QoS of accessing the memory device 130.

Further, in some embodiments, the scan manager 113 scans a group of wordlines or particular logical pages of the group of wordlines residing on the memory device 130. In some embodiments, the scans performed by the scan manager 113 can include scans that facilitate read voltage calibration as well as scans that check the data integrity after various read-disturb stresses. For example, the scan manager 113 can perform, on each page in the group, a scan that can be referred to as a valley health check that generates the following data state metric measurements: the valley width between two specified adjacent Vₜ distributions; and the center of the valley (and the shift of the center from a previous measurement). In another example, the scan manager 113 can perform, on each page in the group, a scan referred to as a read disturb scan on the group of pages to obtain the following data state metric measurements: a read count for the page, and the center of the valley between two specified adjacent Vₜ distributions (and the shift of the center from a previous measurement).

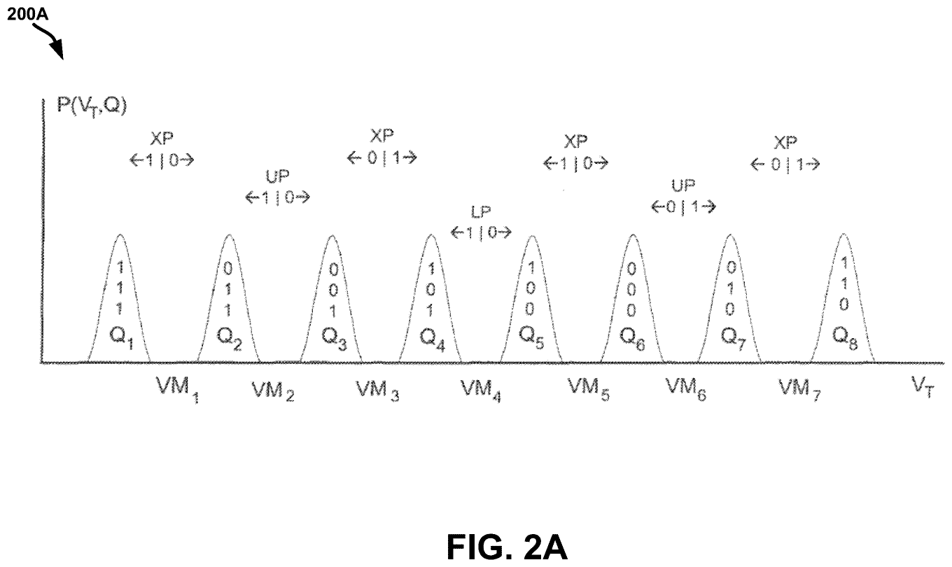

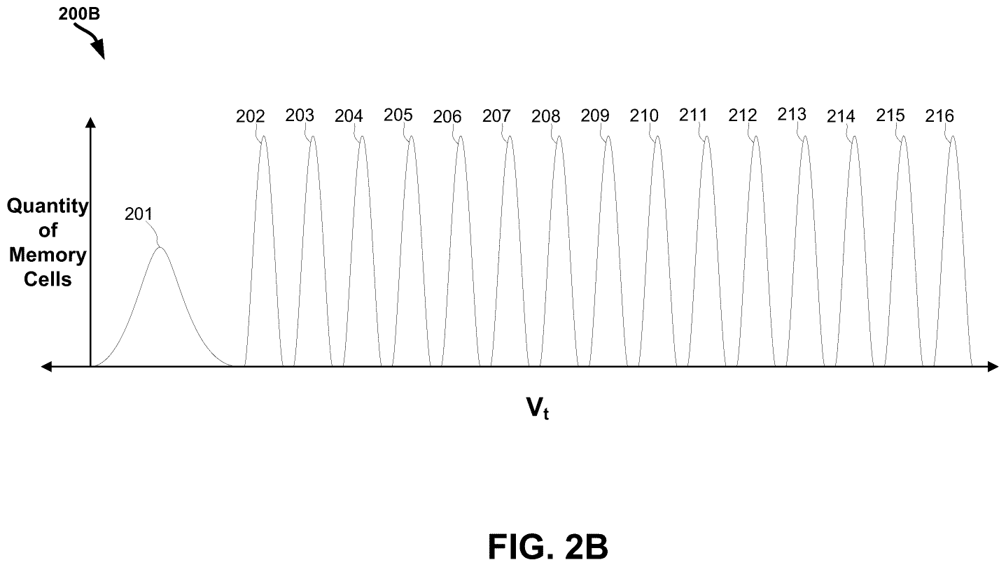

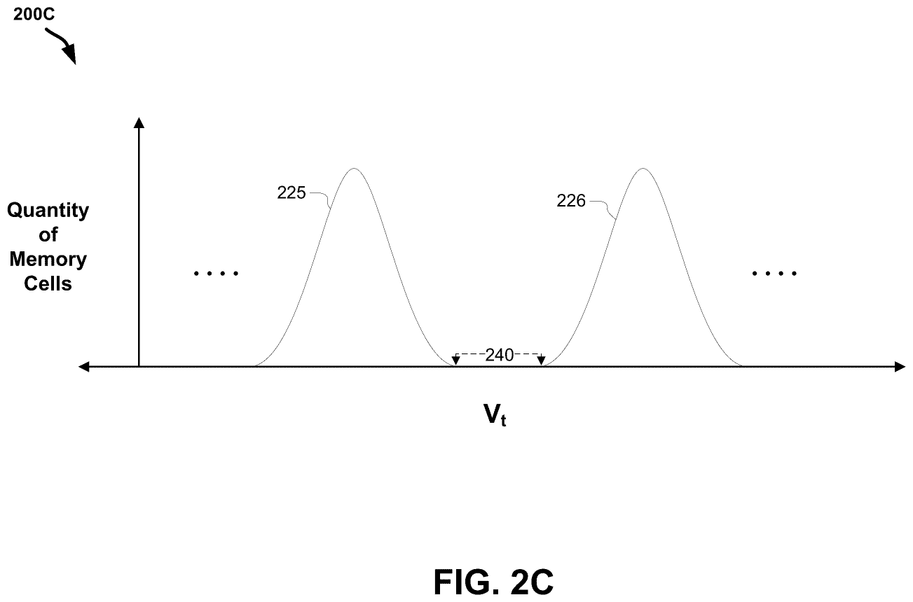

As will be described in more detail with reference to FIGS. 2B-2C, the values of the data state metrics directly obtained by the scans performed by the scan manager 113 can reflect, e.g., through an application of a known mathematical transformation, the measure of another data state metric. For example, by performing a valley health check scan, the scan manager 113 can obtain an error count at one valley margin (EC₁) and an error count at another valley margin (EC₂) to derive the valley width which can be represented by log 10(((EC₁)+(EC₂))/2) Similarly, by performing a valley health scan, the scan manager 113 can obtain a current measure of a valley center to derive the valley shift by subtracting a previous measure of the valley center from the current measure of the valley center. Analogously, by performing a read disturb scan, the scan manager 113 can obtain a current measure of a read count to derive a value of a logarithm of the read count (i.e. log 10(Read Count) that can be matched with a corresponding valley width value.

Accordingly, in some embodiments, the scan manager 113 identifies, among the wordlines on the memory device 130, a group of wordlines, where each wordline of the group of wordlines is connected to a respective subset of memory cells. In some embodiments, the scan manager 113 can identify the wordlines in a group based on a parameter that determines a location or property of the cells on the wordline. For example, the scan manager 113 can select a set of wordlines to scan (a “scan group”) where each wordline is selected based on a parameter that determines a location or property of the cells on the wordline (e.g., the index of the wordline within a particular page, the SCL susceptibility of the wordline, the indicator of which die/plane/block the wordline is on, etc.). In one embodiment, the wordlines can be selected such that a representative sampling of wordlines shares a particular parameter from part of the scan group. In several embodiments the identified group of wordlines that form part of the scan group can include wordlines connected to memory cells programmed to logical states within one or more logical pages.

Thus, in some embodiments, the scan manager 113 can assign, to the group of wordlines, a specified charge loss classification value corresponding to a shift of a threshold voltage distribution. For example, the scan manager 113 can use statistical or experimental data to determine the respective measures of SCL susceptibility of one or more wordlines and, on that basis, assign a charge loss classification value that characterizes the shift of a threshold voltage distribution on those wordlines. In some embodiments, the scan manager 113 can identify the wordlines having the same or similar SCL susceptibility measures and assign a corresponding charge bucket classifier (CBC) index value to each of the wordlines in the group or to the entire group, by recording the assigned CBC index value as metadata associated with respective identifiers of the wordlines in the group.

Further, the scan manager 113 can select a page level within a page level hierarchy, where the selected page level includes a particular set of memory cell charge states. The scan manager 113 can then select a set of memory cells that has one or more memory cells having their respective charge states correspond to the page level (e.g., the cells whose charge state is within the page level). The page level hierarchy and the correspondence of particular logical memory pages within a physical memory page to respective sets of memory cell charge states can be further understood with reference to FIG. 2A, which schematically illustrates a distribution 200A of threshold control gate voltages for a memory cell capable of storing three bits of data by programming the memory cell into at least eight charge states that differ by the amount of charge on the cell's floating gate.

FIG. 2A shows distributions 200A of threshold voltages P(V_{T}, Qₖ) for 2N 8 different charge states of a tri-level cell (TLC) separated with 2³−1=7 valley margins VMₖ. Accordingly, a memory cell programmed into a k-th charge state (e.g., having the charge Qₖ deposited on its floating gate) can be storing a particular combination of N bits (e.g., 0110, for N=4). This charge state Qₖ can be determined during a readout operation by detecting that a control gate voltage V_{CG} within the valley margin VMₖ is sufficient to open the cell to the source-drain current whereas a control gate voltage within the preceding valley margin VMₖ₋₁ is not.

In general, storage devices can be classified by the number of bits stored by each cell of the memory. For example, as noted above, a single-level cell (SLC) memory has cells that can each store one bit of data (N=1) and multi-level memories have cells that can each store multiple bits of data (N=2+). Of multiple-level-cell memories, a multi-level cell (MLC) memory has cells that can each store up to two bits of data (N=2), a tri(ple)-level cell (TLC) memory has cells that can each store up to three bits of data (N=3), and a quad-level cell (QLC) memory has cells that can each store up to four bits of data (N=4). In some storage devices, each wordline of the memory can have the same type of cells within a given partition of the memory device. Accordingly, in some devices, all wordlines of a block or a plane can be SLC memory, or all wordlines can be MLC memory, or all wordlines can be TLC memory, or all wordlines can be QLC memory. Because in some devices, an entire wordline is biased with the same control gate voltage V_{CG} during write or read operations, a wordline in SLC memory typically hosts one memory page (e.g., a 16 KB or a 32 KB page) that is programmed in one setting (by selecting various bitlines consecutively). A wordline of a higher-level (MLC, TLC, or QLC) memory cell can host multiple pages on the same wordline. Different pages can be programmed (by the scan manager 113 of memory controller 115 via electronic circuitry) in multiple settings. For example, in some embodiments, after a first bit is programmed on each memory cell of a wordline, adjacent wordlines can first be programmed before a second bit is programmed on the original wordline. This can reduce electrostatic interference between neighboring cells. The memory controller 115, via scan manager 113, can program a state of the memory cell and then read can read this state by comparing a read threshold voltage V_{T} of the memory cell against one or more read level thresholds. The operations described herein can be applied to any N-bit memory cells.

For example, a TLC can be capable of being in one of at least eight charging states Qₖ (where the first state can be an uncharged state Q₁=0) whose threshold voltage distributions are separated by valley margins VMₖ that can be used to read out the data stored in the memory cells. For example, if it is determined during a read operation that a read threshold voltage falls within a particular valley margin of 2N−1 valley margins, it can then be determined that the memory cell is in a particular charge state out of 2N possible charge states. By identifying the right valley margin of the cell, it can be determined what values all of its N bits have. The identifiers of valley margins (such as their coordinates, e.g., location of centers and widths) can be stored in a read level threshold register of the memory controller 115.

The read operation can be performed after a memory cell is placed in one of its charged states Qₖ by a previous write operation. For example, to program (write) 96 KB (48 KB) of data onto cells belonging to a given wordline M of a TLC, a first programming pass can be performed. The first programming pass can store 32 KB (16 KB) of data on the wordline M by placing appropriate charges on the floating gates of memory cells of the wordline M. For example, a charge Q can be placed on the floating gate of a specific cell. A cell is programmed to store value in its lower-page (LP) bit if the cell is charged to any of the charge states Q₁, Q₂, Q₃, or Q₄. The cell is programmed to store value 0 in its LP bit if the cell is charged to any of the charge states Q₅, Q₆, Q₇, or Q₈. As a result, during a read operation it can be determined that the applied control gate voltage V_{CG} placed within the fourth valley margin VM₄ is sufficient to open the cell to the source-drain electric current. Hence, it can be concluded that the cell's LP bit is in logical state 1 (e.g., being in one of the charge states Qₖ with k≤4). Conversely, during the read operation it can be determined that the applied control gate voltage V_{CG} within the fourth valley margin is insufficient to open the cell to the source-drain electric current. Hence, it can be concluded that the cell's LP bit is in logical state 0 (i.e., being in one of the charge states Qₖ with k≥4).

In some embodiments, after cells belonging to the M-th wordline have been programmed as described, the LP has been stored on the M-th wordline and the programming operation can proceed with additional programming passes to store an upper page (UP) and an extra page (XP) on the same wordline. Although such passes can be performed immediately after the first pass is complete (or even all pages can be programmed in one setting), in order to minimize errors it can be advantageous to first program LPs of adjacent wordlines (e.g., wordlines M+1, M+2, etc.) prior to programming UP and XP into wordline M.

When the UP is to be programmed into wordline M, a charge state of a memory cell can be adjusted so that its distribution of threshold voltages is further confined to be within a known set of valley margins VM. For example, a cell that is in one of the charge states Q₁, Q₂, Q₃, or Q₄ (i.e., a cell accorded a logical bit state of 1 for LP programming) can be charged to just one of two states Q₁ or Q₂, in which case the cell is to store value 1 in its UP bit. Conversely, a cell can be charged to one of two states Q₃ or Q₄ to store value 0 in its UP bit. As a result, during a read operation it can be determined that the applied control gate voltage V_{CG} within the second valley margin VM₂ is sufficient to open the cell to the source-drain electric current. Hence, it can be concluded that the cell's UP bit is in a logical bit state of 1 (i.e., being in one of the charge states Qₖ with k≤2). Conversely, during a read operation it can be determined that the applied control gate voltage V_{CG} within the second valley margin VM₂ is insufficient to open the cell to the source-drain electric current. Hence, it can be concluded that the cell's UP bit is in a logical state of 0 (i.e., being in one of the charge states Qₖ with 2<k≤4). Likewise, charge states Q₅, Q₆, Q₇, or Q₈ (accorded bit 0 status for LP programming) can be further driven to the states Q₅ or Q₆ (UP bit value 0) or the states Q₇ or Q₈ (UP bit value 1).

Similarly, the extra page (XP) can be programmed into the wordline M by further adjusting the charge state of each memory cell. For example, a cell that is in the logical state of 10 (i.e., UP bit stores value 1 and LP bit stores value 0) and is in one of the charge states Q₇ or Q₅ can be charged to state Q₇ to store a value of 0 in its XP bit (i.e., logical state 010). Alternatively, the cell can be charged to charge state Q₅ to store a value of 1 in its XP bit (i.e., a logical state 110). As a result, during a read operation it can be determined that the applied control gate voltage V_{CG} within the seventh valley margin is insufficient to open the cell to the source-drain electric current. Hence, the memory controller 115 can determine that the cell's logical state is 110 (corresponding to charge state Q₇). Conversely, during a read operation it can be determined that the applied control gate voltage V_{CG} within the seventh valley margin VM₇ is sufficient to open the cell to the source-drain electric current. Hence, the memory controller 115 can determine that the cell's XP bit stores a value of 0. If it is further determined that control gate voltages V_{CG} within the first six valley margins are insufficient to open the cell to the electric current, the memory controller 115 can ascertain the logical state of the cell as 010 (i.e., corresponding to the charge state Q₇).

Accordingly, the scan manager 113 can select a page (i.e., a logical page) among multiple levels of the page level hierarchy where each level contains different sets of memory cell charge states to which the cells on the wordlines of the identified wordline group might be charged. Each page level can correspond to a logical page type that includes a particular set of charge states (e.g., programming levels or logical states to which the memory cells can be programmed). For example, the QLC memory cells connected to the wordlines of the wordlines group can be programmed to a state that is part of one of four logical pages, such as a lower page (LP), upper page (UP), extra page (XP), and top page (TP). The memory cells can be programmed to an erased state or can be programmed to one of fifteen other programming levels each of which can belong to one of the pages LP, UP, XP, or TP.

Having selected the group of wordlines and the logical page which is to be scanned, the scan manager 113 can scan the group of wordlines. For example, the scan manager 113 can scan the wordlines in the group of wordlines that belong to the selected logical page (i.e., that are connected to memory cells that are programmed to a programming level within the selected logical page). Each scan can include performing a coarse read calibration and can also include performing a fine read calibration each of which involves the application of one or more read reference voltages that can be offset relative to an initially applied read reference voltage and can include determining one or more data state metric values such as an RBER or an EC for the memory cells and wordlines being scanned. To perform a coarse read calibration, the scan manager can apply a read reference voltage determined based on offsets recorded in a calibration table (e.g., a coarse calibration table containing an entry indicating an offset value relative to a default read-reference voltage for reading a memory cell programmed to a particular programming level. To scan a memory cell on one of the wordlines in the group, the scan manager 113 can apply read reference voltage determined by referencing the calibration table, e.g., a default pre-determined read reference voltage recorded in a setting of the memory device 130 used to read a memory cell programmed to a particular logical state adjusted by a corresponding offset determined based on the CBC index value of the wordline to which the memory cell is connected. Thus, in some embodiments, the scan manager 113 can scan the group of wordlines by applying one or more sequences of read reference voltage pulses to the memory cells connected to the group of wordlines.

Accordingly, in some embodiments, the scan manager 113 can select a set of memory cells the respective charge states of which correspond to the page level (i.e., a set of memory cells all charged to a charge state within the set of charge states of the selected page level). The scan manager 113 can then determine, for the set of memory cells whose charge state is within the page level (i.e., whose programmed logical state is within the logical page) that was selected, an aggregate respective values of one or more data state metrics. In the various embodiments, the scan manager 113 can determine an aggregate value for each of the data state metrics that it measures during the scan. In some embodiments, the data state metric that is determined can be a raw bit error rate (RBER) and can also be an error count (EC). Accordingly, in some embodiments, the scan manager can determine an aggregate raw bit error rate (RBER) value. In the same or other embodiments, the scan manager can determine an aggregate error count (EC).

In some embodiments, the scan manager 113 can determine whether a determined individual or aggregate value of a measured data state metrics satisfies a criterion. For example, in some cases the criterion can be satisfied if the value is equal to or exceeds a pre-determined threshold value (e.g., when an RBER is greater than N bit-errors/ms). In other cases, the criterion can be satisfied if the value is equal to or is less than a pre-determined threshold value (e.g., when an EC is less than M errors). Thus, in some embodiments, the scan manager 113 can determine whether the aggregate value of the data state metric satisfies the criterion (e.g., the RBER criterion). The scan manager 113 can determine whether the aggregate RBER value exceeds the threshold value of N. Responsive to determining that the aggregate value of the data state metric satisfies a first criterion (e.g., responsive to determining that the aggregate RBER value satisfies the first criterion because the measured aggregate RBER value is equal to or greater than the pre-determined threshold value of N), the scan manager 113 can identify, among the set of memory cells, another set of memory cells charged to a specified charge state within the page level that was selected. For example, when scanning a group of wordlines within the TP, in response to determining that the aggregate RBER value exceeds the threshold value, the scan manager 113 can identify the memory cells programmed to programming level L5.

In the same or other embodiments, having identified the memory cells programmed to a logical state within the page (e.g., L5 in the TP), the scan manager 113 can, determine, for this other set of memory cells, an aggregate value of another data state metric based on one or more distributions of individual values of this data state metric. For example, the scan manager 113 can apply another one or more sequences of read reference voltage pulses to the memory cells connected to the group of wordlines or to a set of wordlines within the group. In the various embodiments, each of the sequences of voltage pulses can include one or more groups of read reference voltage pulses, where each group of read reference voltage pulses generates a corresponding distribution of individual values of a data state metric (e.g., RBER, EC). Each of the data state metric values can respectively have a corresponding read reference voltage from which it is generated. Thus, the scan manager 113 can apply another sequence of read reference voltage pulses to the memory cells connected to the group of wordlines, and generate a corresponding distribution of individual ECs, each individual EC corresponding to a respective read reference voltage.

FIG. 2B is a graph 200B of an example set of threshold voltage distributions of multiple memory cells of a memory array in a memory device in accordance with some embodiments of the present disclosure. In some embodiments, memory cells on a block of a memory device (e.g., memory device 130 of FIG. 1) can have different Vₜ values an aggregate representation of which for a set of these memory cells can be shown with plots on a graph such as graph 200B. For example, a set of Vₜ ranges and their distributions for a group of sixteen-level memory cells, e.g., QLC memory cells is depicted in FIG. 2B. In some embodiments, each of these memory cells can be programmed to a Vₜ that is within one of sixteen different threshold voltage ranges 201-216. Each of the different Vₜ ranges can be used to represent a distinct programming state that corresponds to a particular pattern of four bits. In some embodiments, the threshold voltage range 201 can have a greater width than the remaining threshold voltage ranges 202-216. This can be caused by the memory cells initially all being placed in the programming state corresponding to the threshold voltage range 201, after which some subsets of those memory cells can be subsequently programmed to have threshold voltages in one of the threshold voltages ranges 202-216. Because write (i.e., programming) operations can be more precisely controlled than erase operations, these threshold voltage ranges 202-216 can have more narrow distributions.

In some embodiments, the threshold voltage ranges 201, 202, 203, 204, 205, 206, 207, 208, 209, 210, 211, 212, 213, 214, 215, and 216 can each represent a respective programming state (e.g., represent L0, L1, L2, L3, L4, L5, L6, L7, L8, L9, L10, L11, L12, L13, L14 and L15 respectively). For example, if the Vₜ of a memory cell is within a first threshold voltage range 201 of the sixteen threshold voltage ranges, the memory cell in this case can be said to be in a programming state L0 corresponding to the memory cell storing a 4-bit logical value of ‘1111’ (this can be referred to as the erased state of the memory cell). Thus, if the threshold voltage is within a second threshold voltage range 202 of the sixteen threshold voltage ranges, the memory cell in this case can be said to be in a programming state L1 corresponding to the memory cell storing a 4-bit logical value ‘0111’. If the threshold voltage is within a third threshold voltage range 203 of the sixteen threshold voltage ranges, the memory cell in this case can be storing a programming state L2 having a 4-bit logical value ‘0011,’ and so forth through all 16 threshold voltage ranges. In some embodiments, a correspondence table such as Table 1 can provide a correspondence between the states of the memory cells and their corresponding logical values. Other associations of programming states to corresponding logical data values are envisioned. For the purposes of this disclosure, memory cells that are in the lowest state (e.g., the erased state or L0 data state) can be referred to as unprogrammed, erased, or set to the lowest programming state.

TABLE 1

| | Logical | | Logical |
|---|---|---|---|
| Programming | Programming | Programming | Data |
| State | Value | State | Value |
| L0 | 1111 | L8 | 1100 |
| L1 | 0111 | L9 | 0100 |
| L2 | 0011 | L10 | 0000 |
| L3 | 1011 | L11 | 1000 |
| L4 | 1001 | L12 | 1010 |
| L5 | 0001 | L13 | 0010 |
| L6 | 0101 | L14 | 0110 |
| L7 | 1101 | L15 | 1110 |

Notably, the distributions 201-216 can be separated by valleys of varying widths. Furthermore, with time and continued use, the depicted distributions and valleys can shift and change in width. The data state metric of voltage shift obtained from various scans performed by the embodiments described herein can be obtained for various valleys, such as the fifteenth valley between adjacent distributions (i.e., valley between distributions 215-216) or the first valley between adjacent distributions (i.e., valley between distributions 201-202). Accordingly, the scans described herein involve distinguishing one state of a memory cell from another and determining data state metrics associated with the depicted distributions and valleys. This relationship is further clarified by focusing on memory cell states represented by two adjacent Vₜ distributions, as explained in more detail with reference to FIG. 2C.

FIG. 2C is a graph 200C of two example threshold voltage distributions of multiple memory cells of a memory array in a memory device in accordance with some embodiments of the present disclosure. Consider the depiction FIG. 2C of an example Vₜ distribution 225-226 to be analogous to a pair of adjacent Vₜ distributions from graph 200B of FIG. 2B. For example, the Vₜ distributions 225-226 of FIG. 2C can represent some portion of the distributions for threshold voltage ranges 201-216 of FIG. 2B after the completion of a write (i.e., programming) operation for a group of memory cells. As seen in FIG. 2C, adjacent threshold voltage distributions 225-226 can be separated by a valley with margins 240 (e.g., empty voltage level space) at the end of a programming operation. Applying a read voltage (i.e., sensing voltage) between the margins 240 to the control gates of the group of memory cells can be used to distinguish between the memory cells of the threshold voltage distribution 225 (and any lower threshold voltage distribution) and the memory cells of the threshold voltage distribution 226 (and any higher threshold voltage distribution).

Due to a phenomenon called charge loss, which can include quick charge loss (QCL) and slow charge loss (SCL), the threshold voltage of a memory cell can change over time as well as when exposed to higher temperatures as the electric charge contained in the cell degrades. As previously discussed, this change results in a shift of the Vₜ distributions over time and can be referred to as a temporal Vₜ shift (since the degrading electric charge causes the voltage distributions to shift along the voltage axis towards lower voltage levels and causes the valley defined by margins 240 to narrow over time). Further, during the operation of a memory device, the QCL can be caused by the threshold voltage changing rapidly at first (immediately after the memory cell was programmed), after which the effect of SCL becomes more evident as the Vₜ shift slows down in an approximately logarithmic linear fashion with respect to the time elapsed since the cell was programmed.

In various embodiments, this temporal Vₜ shift, if left unadjusted, can narrow the valley width between distributions 225 and 226 (i.e., can reduce the read window between the margins 240 at the edges of the threshold voltage distributions 225-226) over time, and can cause these threshold voltage distributions 225 and 226 to overlap, making it more difficult to distinguish between cells whose actual Vₜ is within the range of one of the two adjacent Vₜ distributions 225-226. Accordingly, failure to mitigate the temporal Vₜ shift (e.g., caused by the SLC) can result in the increased trigger rate and bit error rate in read operations. Further, failing to address or account for the Vₜ shift across all Vₜ distributions can cause increases in read errors, resulting in a high read trigger rate, which in turn negatively impacts overall latency, throughput, and QoS of a memory device. The numbers of distributions, programming levels, and logical values in the illustrative examples of FIGS. 2B-2C are chosen for illustrative purposes and are not to be interpreted as limiting, other embodiments can use various other numbers of distributions, associated programming levels, and corresponding logical values can be used in the various embodiments disclosed herein.

In various embodiments, with additional reference to FIG. 1, the scan manager 113 stores and tracks attributes, e.g., total bytes written (TBW), temperature change over time, as well as representative data state metrics for blocks of memory cells based on read sampling certain pages of each block associated with BGMS. These attributes may be used individually or as a combination to determine whether BGMS-sampled blocks qualify for data refresh. As was discussed, the degree of degradation of memory cells in particular memory blocks can be reflected by and can correspond to various respective values of data state metrics, e.g., valley shift values, read counts, valley width values, error counts, RBER, RWB, and the like.

In some embodiments, the BGMS-related scanning is also or alternatively related to Self-Monitoring Analysis and Reporting Technology (e.g., S.M.A.R.T.). In some embodiments, S.M.A.R.T. is a protocol scan command that enables the scan manager 113 to retrieve scan-based data (including BGMS-related data) from the memory device 130 to analyze in relation to health of various memory blocks (or other units of memory) of the memory device 130. This S.M.A.R.T. technology is intended to recognize conditions that indicate memory device degradation and is designed to provide sufficient warning of a failure to allow data back-up before an actual failure occurs. In some embodiments, the scan manager 113 monitors specific attributes for degradation over time but cannot predict instantaneous memory device failures. Each attribute monitors a specific set of conditions in the operating performance of the memory device 130, and the thresholds are optimized to minimize false predictions.

In at least some embodiments, the scan manager 113 stores the metadata associated with attributes associated with BGMS scanning to memory, e.g., to the local memory 119 and/or to the memory device 130. In some embodiments, for example, this metadata may be instantiated as firmware values stored to NVM of the memory device 130 and may be cached in the local memory 119 during use. The scan manager 113 can periodically analyze this metadata relative to memory cell degradation (e.g., associated with different attributes) and decide, on a block-by-block basis, whether each block qualifies for a data refresh. The scan manager 113 can initiate a refresh operation for each block that satisfies particular criteria (e.g., threshold values for respective attributes) intended to trigger such a refresh operation. The scan manager 113 may cause an indicator for each block to be refreshed to be stored (or buffered) in the refresh queue 121 of the volatile memory, e.g., so that refresh data for each respective block may be eventually written to new (e.g., erased) memory blocks. In this way, the refresh data is rewritten to erased blocks with newly set threshold voltage levels that also resets the read voltage reference levels, which is intended to reduce read errors and protect from data degradation that may lead to data loss. In some embodiments, memory blocks that are overly degraded may be marked as bad so not be used again in the future.

In some embodiments of refreshing multi-level cell data (e.g., MLC, TLC, QLC, or PLC data), the scan manager 113 performs a media management operation, e.g., by folding the block to be refreshed before being read and written to an erased block of the IC memory device 130. For example, the data of a memory block may be folded if any codeword demonstrates a trigger rate or reliability risk that satisfies particular criteria that has been discussed. The folding operation may involve relocating the data stored at the affected block of the memory device to another block. Because full scans are time-consuming, a sampling scan may be performed in which one or more pages of each block is read or tracked in terms of the attributes and data state metrics.

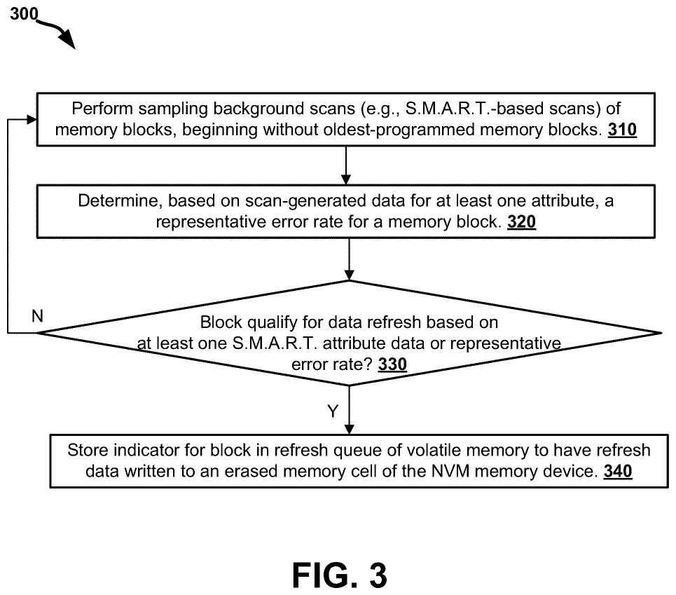

FIG. 3 is a flow diagram of an example method 300 for executing data refresh in particular memory blocks based on results of background media scans of those memory blocks in accordance with some embodiments. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the scan manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel.

At operation 310, the processing logic performs one or more sampling background scans of the one or more blocks of memory. In some embodiments, these sampling background scans (e.g., BGMS-based scanning) begins with the oldest-programed memory blocks first, as these memory blocks would be expected to be the most degraded memory blocks. Because the sampling background scanning may be confined in some embodiments to idle time or just when the memory device 130 is being written (no read operations), the prioritization of which memory blocks get scanned first may aid in identifying sooner the memory blocks that may need to be refreshed.

At operation 320, the processing logic determines, based on scan-generated data for at least one attribute, a representative error rate for a memory block. In some embodiments, for example, this scan-generated data may be instantiated as firmware values stored to NVM of the memory device 130 and may be cached in the local memory 119 during use, for example. Iin some embodiments, analysis may be performed on the scan-generated data associated with attributes for which particular threshold values or overall counts may dictate when a representative error rate is incremented or decremented. Hardware or software counters may be employed to track how many times a particular threshold value is satisfied in order to track overall error rate for each attribute. As discussed, the attributes may include TBW, temperature change over time, and/or a data state metric such as those discussed previously.

At operation 330, the processing logic determines whether the memory block qualifies for refresh based on at least one attribute of self-monitoring analysis and reporting technology (S.M.A.R.T.) data obtained from the one or more sampling background scans or based on a representative error rate that was determined at operation 320. For example, in some embodiments, the representative error rate for each block and for a particular attribute may be predictive of failure of a respective block. Thus, a threshold error rate for a particular attribute may be satisfied, which triggers qualification for a data refresh. If a particular block does not qualify for data refresh, the method 300 continues back to operation 310 where scanning and analysis of data that results from the scanning is continued to be performed.

In response to a block qualifying, at operation 330, for data refresh, the processing logic, at operation 340, stores the indicator for the memory block in the refresh queue 121 of volatile memory, the memory block to be folded, read, and written to an erased memory cell of the memory device 130. The data for that indicators that are enqueued for refresh may be referred to as refresh data. For example, in some embodiments, the refresh data in is a type of multi-level cell data, and thus the processing logic folds the portion of the refresh data before the refresh data is written to one or more erased blocks of the IC memory device 130.

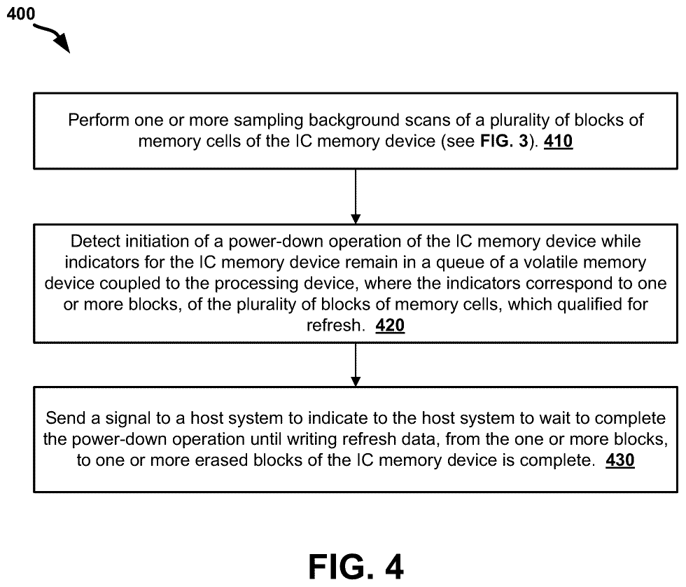

FIG. 4 is a flow diagram of an example method for efficiently managing background media scans in non-volatile memory devices in accordance with some embodiments. The method 400 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 400 is performed by the scan manager 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel.

At operation 410, the processing logic performs one or more sampling background scans of a plurality of blocks of memory cells of the IC memory device.

At operation 420, the processing logic detects initiation of a power-down operation of the IC memory device while indicators for the IC memory device remains in a queue of a volatile memory device coupled to the processing device. The power-down operation may be either of a power-off (e.g., shutdown) or a move to a low-power state. The queue may be, for example, the refresh queue 121 (FIG. 1). In some embodiment, the indicators correspond to, or identify, one or more blocks, of a plurality of blocks of memory cells, which qualified for refresh.

At operation 430, the processing logic sends a signal to a host system (e.g., the host system 120), the signal to indicate to the host system to wait to complete the power-down operation until writing refresh data, from the one or more blocks, to one or more erased blocks of the IC memory device is complete. In some embodiments, the signal includes the number of indicators that remain in the refresh queue 121. Because the host system 120 tracks the data type, the host system 120 may be able to determine an expected amount of time remaining until the memory blocks that correspond to the indicators in the queue 121 will be refreshed.

In some embodiments of the method 400, the processing logic further determines, based on a number and data type of blocks for which indicators remain in the queue, an amount of time to empty the queue. For example, the type of blocks can be SLC, MLC, TLC, QLC, and/or PLC (depending on memory device configuration). In some embodiments, for purposes of explanation only, a block may take a second to program. Thus, if 10 blocks of refresh data is stored in the refresh queue 121, then the amount of time may be calculated as approximately 10 seconds. In these embodiments, the signal from the scan manager 113 includes the amount of time to delay the power-down operation. In some embodiments, the signal may also, or alternatively, include a flag that specifies an urgency level (e.g., low, medium, high) associated with the refresh so that the host 120 can decide whether to wait or proceed with the power-down operation. For example, the urgency level may be based on an age of the data, whether folding of the data has occurred (and is thus mid-process of being refreshed), an error level (e.g., RBER) associated with the data, or the like.

In some embodiments of the method 400, the processing logic monitors the queue 121 to detect when the queue becomes empty of the identifiers and, in response to detecting that the queue is empty, informs the host system 120 to complete the power-down operation. In various embodiments, the host system 120 polls the controller 115 (e.g., a register of the controller 115) that indicates whether the volatile memory still contains refresh data that needs to be programmed to the IC memory device. Thus, a response to that polling inquiry may be considered the signal from the memory sub-system. In this way, the host system 120 may also be configured to be aware of or waiting for such a signal to know when it is safe to completely power off the memory sub-system and thus also the memory device.

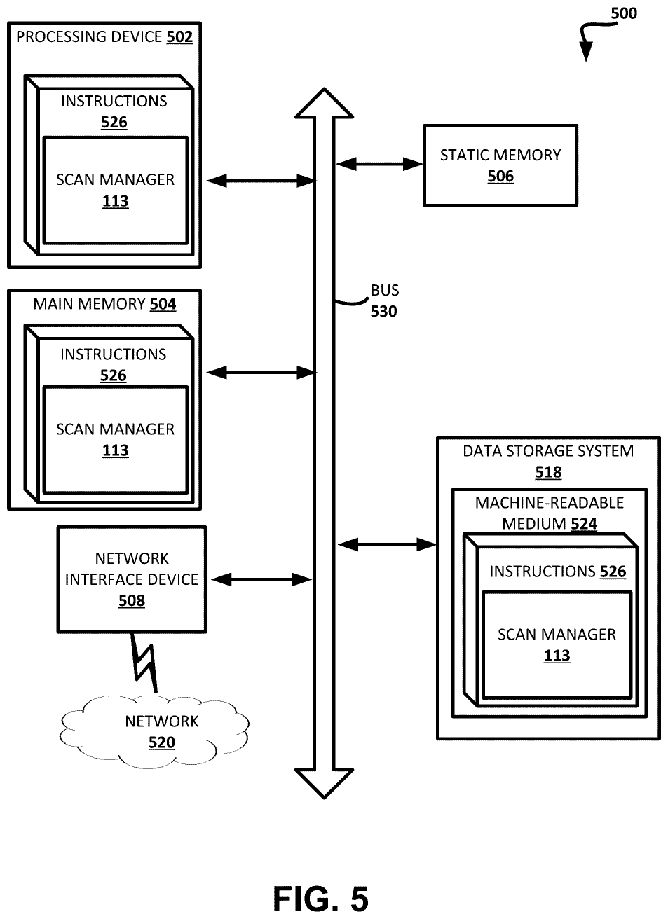

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the scan manager 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium or non-transitory computer-readable storage medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a scan manager (e.g., the scan manager 113 of FIG. 1 and the methods 300 and 400 of FIGS. 3 and 4, respectively). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, which manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a non-transitory computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
an integrated circuit (IC) memory device comprising memory cells;
a volatile memory device comprising a queue to store indicators for one or more blocks of the memory cells that are to be refreshed; and
a processing device operatively coupled to the IC memory device and the volatile memory device, the processing device to perform operations comprising:
detecting initiation of a power-down operation of the system; and
in response to detecting the initiation of the power-down operation:
detecting that one or more indicators remain in the queue corresponding to the one or more blocks of the memory cells; and
sending a signal to a host system coupled to the processing device, the signal to indicate to the host system to wait to complete the power-down operation until writing refresh data, from the one or more blocks, to one or more erased blocks of the IC memory device is complete.

2. The system of claim 1, wherein the operations further comprise:
performing one or more sampling background scans of the one or more blocks; and
determining that the one or more blocks qualify for refresh based on at least one attribute of self-monitoring analysis and reporting technology (S.M.A.R.T.) data obtained from the one or more sampling background scans.

3. The system of claim 2, wherein the at least one attribute comprises one or more of total bytes written (TBW), temperature change over time, or a data state metric.

4. The system of claim 1, wherein the operations further comprise:
performing one or more sampling background scans of the one or more blocks to determine a representative error rate of each respective block of the memory cells; and
determining, based on the representative error rate for each respective block, that the one or more blocks qualify for refresh.

5. The system of claim 1, wherein the operations further comprise determining, based on a number and data type of the one or more blocks, an amount of time to empty the queue, and wherein the signal includes the amount of time to delay the power-down operation.

6. The system of claim 5, wherein the signal further includes a flag that specifies an urgency level associated with the refresh so that the host system can decide whether to wait or proceed with the power-down operation.

7. The system of claim 1, wherein the one or more indicators comprise one or more identifiers, and wherein the operations further comprise:
monitoring the queue to detect when the queue becomes empty of the one or more identifiers; and
in response to detecting that the queue is empty, informing the host system to complete the power-down operation.

8. A method comprising:
performing, by a processing device coupled to an IC memory device, one or more sampling background scans of a plurality of blocks of memory cells of the IC memory device;
detecting initiation of a power-down operation of the IC memory device while indicators for the IC memory device remain in a queue of a volatile memory device coupled to the processing device, wherein the indicators correspond to one or more blocks, of the plurality of blocks of memory cells, which qualified for refresh; and
sending, by the processing device, a signal to a host system, the signal to indicate to the host system to wait to complete the power-down operation until writing refresh data, from the one or more blocks, to one or more erased blocks of the IC memory device is complete.

9. The method of claim 8, further comprising determining that the one or more blocks qualify for refresh based on at least one attribute of self-monitoring analysis and reporting technology (S.M.A.R.T.) data obtained from the one or more sampling background scans.

10. The method of claim 9, wherein the at least one attribute comprises one or more of total bytes written (TBW), temperature change over time, or a data state metric.

11. The method of claim 8, wherein performing one or more sampling background scans of the one or more blocks was to determine a representative error rate of each respective block of memory, the method further comprising determining, based on the representative error rate for each respective block, that the one or more blocks of memory qualify for refresh.

12. The method of claim 8, the method further comprising determining, based on a number and data type of the one or more blocks, an amount of time to empty the queue, and wherein the signal includes the amount of time to delay the power-down operation.

13. The method of claim 8, wherein the signal further includes at least one of:
a number of the indicators that remain in the queue; or
a flag that specifies an urgency level associated with the refresh so that the host system can decide whether to wait or proceed with the power-down operation.

14. The method of claim 8, wherein the indicators comprise identifiers, the method further comprising:
monitoring the queue to detect when the queue becomes empty of the identifiers; and
in response to detecting that the queue is empty, informing the host system to complete the power-down operation.

15. A non-transitory computer-readable storage medium storing instructions, which when executed by a processing device coupled to an IC memory device, cause the processing device to perform operations comprising:
performing one or more sampling background scans of a plurality of blocks of memory cells of the IC memory device;
detecting initiation of a power-down operation of the IC memory device while indicators for the IC memory device remain in a queue of a volatile memory device, wherein the indicators correspond to one or more blocks, of the plurality of blocks of memory cells, which qualified for refresh; and
sending, by the processing device, a signal to a host system, the signal to indicate to the host system to wait to complete the power-down operation until writing refresh data, from the one or more blocks, to one or more erased blocks of the IC memory device is complete.

16. The non-transitory computer-readable storage medium of claim 15, wherein the operations further comprise determining that the one or more blocks qualify for refresh based on at least one attribute of self-monitoring analysis and reporting technology (S.M.A.R.T.) data obtained from the one or more sampling background scans.

17. The non-transitory computer-readable storage medium of claim 15, wherein performing the one or more sampling background scans of the one or more blocks was to determine a representative error rate of each respective block of memory, wherein the operations further comprise determining, based on the representative error rate for each respective block, that the one or more blocks of memory qualify for refresh.

18. The non-transitory computer-readable storage medium of claim 15, wherein the operations further comprise determining, based on a number and data type of the one or more blocks, an amount of time to empty the queue, and wherein the signal includes the amount of time to delay the power-down operation.

19. The non-transitory computer-readable storage medium of claim 18, wherein the signal further includes a flag that specifies an urgency level associated with the refresh so that the host system can decide whether to wait or proceed with the power-down operation.

20. The non-transitory computer-readable storage medium of claim 15, wherein the indicators comprise identifiers, and wherein the operations further comprise:
monitoring the queue to detect when the queue becomes empty of the identifiers; and
in response to detecting that the queue is empty, informing the host system to complete the power-down operation.
